(19) United States
(12) Patent Application Publication
(10) Pub. No.: US 2012/0176177 A1
(43) Pub. Date: Jul. 12, 2012

(54) SWITCH WITH IMPROVED EDGE RATE CONTROL

(76) Inventor: Garret Phillips, Phoenix, AZ (US)

(21) Appl. No.: 13/344,184

(22) Filed: Jan. 5, 2012

Related U.S. Application Data
(60) Provisional application No. 61/430,687, filed on Jan. 7, 2011.

(51) Int. Cl. H03K 17/284

(52) U.S. Cl. 327/399

(57) ABSTRACT

This documents discusses, among other things, apparatus and methods for a switch circuit including a break-before-make delay and a gradual turn-on. In an example, a switch circuit can include a switch transistor having a control node and coupled to a first node and a second node, a delay circuit configured to receive control information and to provide the control information after a delay interval, and a gradual turn-on circuit configured to receive the delayed control information from the delay circuit and to transition the transistor from the off-state to the on-state over a ramp interval in response to the delayed control information.

### CLAIM OF PRIORITY

This patent application claims the benefit of priority, under 35 U.S.C. Section 119(e), to Phillips, U.S. Provisional Patent Application Ser. No. 61/430,687, entitled “SWITCH WITH IMPROVED EDGE RATE CONTROL,” filed on Jan. 7, 2011 (Attorney Docket No. 2921.091PRV), which is hereby incorporated by reference herein in its entirety.

### BACKGROUND

Transistor switches are used in electronic devices to allow and assist the devices to perform many functions, such as switching between data lines in a USB switch. Switches can be designed to handle many different switching conditions, some ideal and some non-ideal. As the switch and device are designed to handle more situations, the cost to manufacture the switch and device can become a drag on the ability to market and sell a product such as low-cost electronic devices.

### OVERVIEW

This documents discusses, among other things, apparatus and methods for a switch circuit including a break-before-make delay and a gradual turn-on. In an example, a switch circuit can include a switch transistor having a control node and coupled to a first node and a second node, a delay circuit configured to receive control information and to provide the control information after a delay interval, and a gradual turn-on circuit configured to receive the delayed control information from the delay circuit and to transition the transistor from the off-state to the on-state over a ramp interval in response to the delayed control information.

This overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally a block diagram of an example switch circuit including a break-before-make (BBM) delay and a gradual turn-on (GTO) circuit.

FIG. 2 illustrates generally an example of an BBM delay circuit.

FIG. 3 illustrates generally an example switch circuit including an example GTO circuit.

FIG. 4 illustrates generally an example of a high speed Universal Serial Bus (USB) switch circuit including a gradual turn-on (GTO) circuit.

### DETAILED DESCRIPTION

The present inventor has recognized, among other things, a switch circuit, such as a Universal Serial Bus (USB) switch circuit that can handle many switching situations, both ideal and non-ideal, using a combination of a Break-Before Make (BBM) circuit and a Gradual Turn-On (GTO) circuit to control the switch. The combination of the BBM circuit and the GTO circuit can delay activation of a function of the switch in response to a change in a switch command of the switch. The BBM circuit can provide a predetermined delay between reception of the change in the switch command and the actual state change of the switch. The GTO circuit can gradually couple or decouple switch terminals of the switch during the state change of the switch. The BBM and GTO circuits can reduce constraints for switch application designs such that switch circuits that include the BBM and GTO capabilities can deal with non-ideal switch events, such as high frequency interference and improper connections/disconnections when switching between data lines. In certain examples, inducing delays into the operation of a switch, such as a passive switch, can mitigate non-ideal switching consequences in a device, such as shorting outputs and high frequency interference. Incorporating both a break-before-make delay and a gradual turn-on into the operation of a switch can further reduce reliance on other devices to deal with these undesired events. In this document, a passive switch includes switches that do not process a received signal but can pass the received signal via a low impedance path from one node to one or more other nodes in an on state, and can isolate the one node from the one or more other nodes in an off state.

Break-Before-Make (BBM) capability can include a delay time between one switch path being disabled and another switch path being enabled. Such a delay can ensure a proper disconnection of the first switch path before making a connection of the other switch path.

Gradual Turn-ON (GTO) capability can include an interval of time during which a new switch path becomes fully enabled once that path is activated, such as an interval of time where the switch path transitions from a high impedance disconnected state to low impedance connected state. In certain examples GTO can reduce high frequency interference (fast turn on edge rates) when a switch path is enabled. In certain examples, GTO can allow for the common mode voltage of differential paths to be established over a period of nanoseconds.

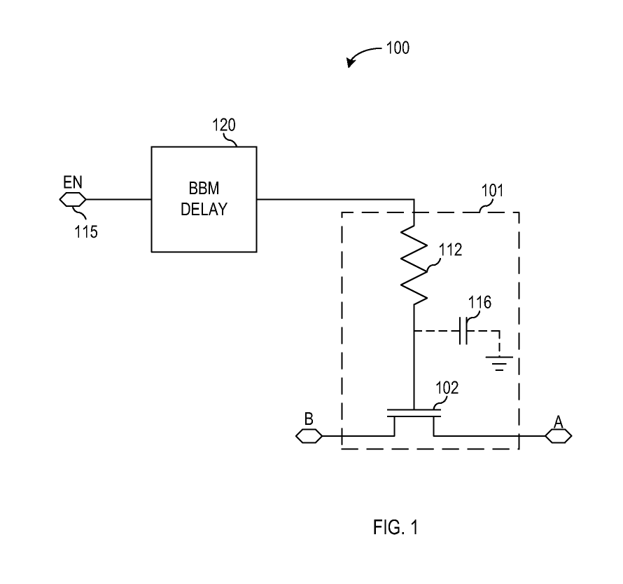

FIG. 1 illustrates generally a switch circuit 100 including a switch transistor 102, a BBM delay circuit 120 and a GTO circuit 101. The switch transistor 102 can include a control node, such as a gate, and first and second switch nodes (A, B). In a first state, an on-state, the switch transistor 102 can couple the first switch node (A) with the second switch node (B) by forming a low impedance path between the first switch node (A) and the second switch node (B). In a second state, an off-state, the switch transistor 102 can isolate the first switch node (A) from the second switch node (B) and vice versa. The state of the switch transistor 102 can be controlled using control information (EN) received at the gate node of the switch transistor 102. In the illustrated example, control information (EN) including a high logic voltage level received at the gate can put the switch transistor 102 in the on-state, and control information (EN) including a low logic voltage level received at the gate can put the switch transistor 102 in the off-state.

In certain examples, the BBM delay circuit 120 can receive the control information (EN) at an enable input 115 of the switch circuit 100. The BBM delay circuit 120 can output the control information (EN) a delay interval after receiving the control information (EN).

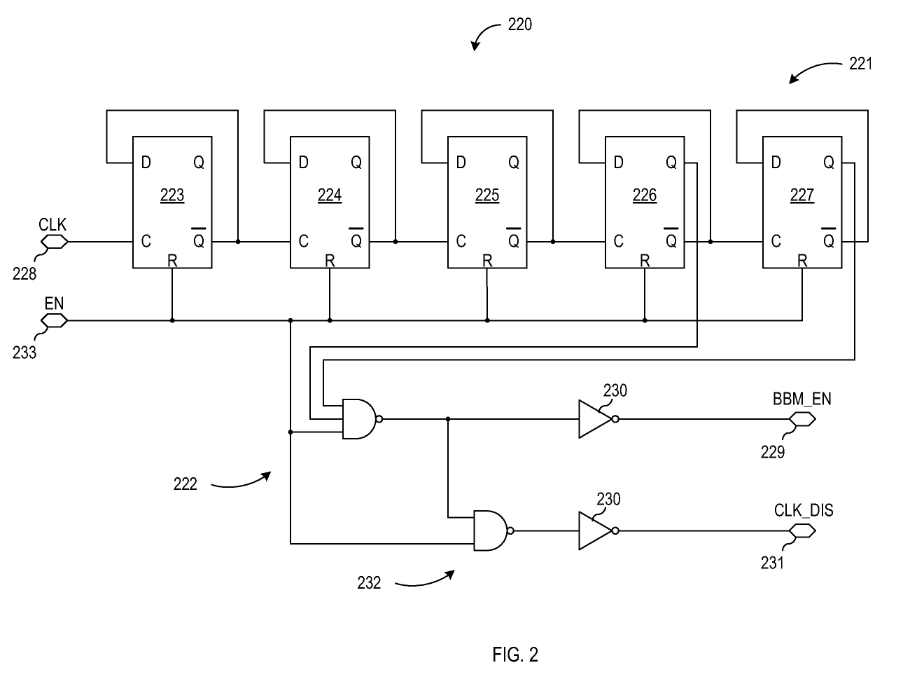

In certain examples, a BBM delay circuit 120 can be implemented using an oscillator (e.g. clock) and a digital counter. After a new switch path is enabled, the counter for that path can be reset and then incremented by the oscillator. The switch function of the switch transistor 102 can activate when the counter reaches a predetermined value. The delay of the BBM delay circuit 120 can allow other circuits that are connected to the first or second switch nodes (A, B) to disconnect before the first and second switch nodes (A, B) are coupled together via low impedance path provided by the switch transistor 102. Such a delay can reduce the probability of unintended circuits being coupled together via the first and second switch nodes (A,B). FIG. 2 illustrates generally an example of a BBM delay circuit.

Referring again the example of FIG. 1, a switch circuit 100 can include a GTO circuit 101 to gradually switch the switch transistor 102 from an off-state to an on-state. Such functionality can reduce high frequency transient noise associated with coupling two nodes together. Gradually switching the switch transistor 102 from an off-state to an on-state can also limit the bandwidth of any signal transients, thus allowing for better filtering of such transients. In some examples, a GTO circuit 101 can be implemented with a BBM delay circuit 120 or can be implemented independently from a BBM delay circuit. A GTO circuit 101 can be implemented using a resistor-capacitor (RC) network coupled to a control node of the switch transistor 102. In an example, a GTO circuit 101 can be implemented using an RC network coupled to a gate of a MOS switch. In certain examples, the capacitance 116 of the RC network can be provided by the capacitance of the switch transistor 102 such that a separate capacitor or capacitive element is not necessary. In an example, upon receiving control information (EN) to enable a switch path, or after a BBM delay interval, voltage can be applied to the control node of the switch transistor 102. The RC network of the GTO circuit can gradually apply the voltage to the control node through the charging delay of the resistor 112 and capacitor 116 of the RC network. In certain examples, as the voltage at the control node increases, the impedance between switch nodes (A, B) of the switch circuit 100 can decrease, for example, in a ramped manner over an interval of time determined by the resistance and capacitance of the RC network. In an example, the resistance of the RC network can be about 50 kOhms. In an example, a GTO circuit 101 can include a resistor 112 with a resistance value of about 5 kOhms to about 50 kOhms. In such an example, parasitic capacitance 116 can allow the gradual turn-on of the switch transistor 102 to occur over an interval of several nanoseconds. It is understood that other resistors, or resistance values, are possible to achieve a desired BBM delay without departing from the scope of the present subject matter.

FIG. 2 illustrates generally an example of a break-before-make (BBM) delay circuit 220. In certain examples, the BBM delay circuit 220 can include a plurality of delay elements 221, and logic elements 222. In an example, the plurality of delay elements 221 can include flip-flops, such as cascaded D-flip-flops 223-227. The cascaded D flip flops 223-227 can be driven by a clock signal (CLK) received at a clock input 228 of the BBM delay circuit 220. In an example, the BBM delay circuit 220 can include a clock to provide the clock signal (CLK). In certain examples, the BBM delay circuit 220 can receive control information at a second input 233. In certain examples, the control information can include an enable signal (EN) configured to enable a switch transistor. In certain examples, the enable signal (EN) can enable the delay elements 223-227. In the example of FIG. 2, the enable signal (EN) can be coupled to the reset input (R) of each of the D flip-flops 223-227. In an example, upon a transition of the enable signal (EN) the D flip-flops 223-227 can be cleared and enabled to receive the clock signal (CLK). On each pulse of the clock signal (CLK), an output of the cascade connected D-flip-flops (223-227) can be sequentially set. When an output of the last D flip-flop 227 is set, the transition of the enable signal (EN) can be provided at an output 229 of the BBM delay circuit 220. In an example, the BBM delay circuit 220 can include additional logic elements, such as inverters 230, to provide the desired logic levels at the components of the BBM delay circuit 220 or to provide the desired logic level at one or more outputs 229, 231 of the BBM delay circuit 220. It is understood that other delay element types and quantities to define a desired delay interval are possible without departing the present subject matter.

In certain examples, the BBM delay circuit 220 can include additional logic 232 to provide a clock disable signal (CLK DIS) at a second output 231 of the BBM delay circuit 220. The clock disable signal (CLK DIS) can be used to disable the clock at the conclusion of the delay interval provided by the BBM delay circuit 220. Disabling the clock can save power that would otherwise be used to provide clock signals outside the delay interval. Such power saving can be significant over the operational charge life of a mobile electronic device.

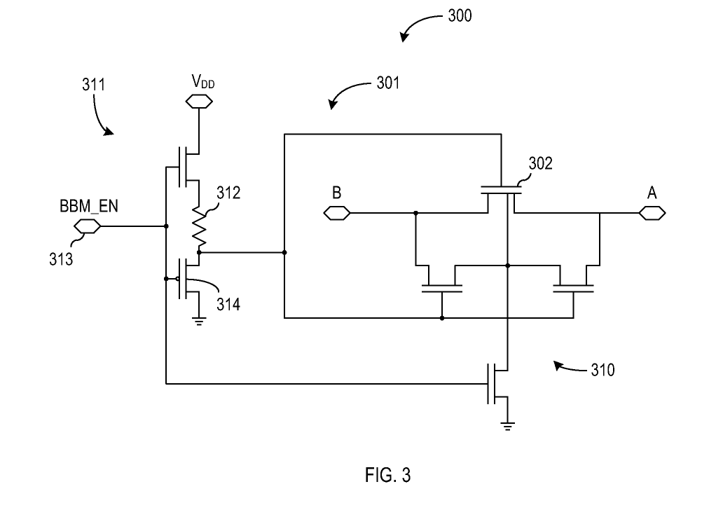

FIG. 3 illustrates generally a switch circuit 300 including a GTO circuit 301. The switch circuit 300 can include a switch transistor 302, well biasing electronics 310, and control node electronics 311 including a resistive element 312 selectively coupled between a control voltage (V_{DD}) and the control node of the switch transistor 302. In certain examples, the switch transistor 302 can be configured to couple, via a low impedance path, a first switch node (A) and a second switch node (B) in an on-state, and to isolate the first switch node (A) from the second switch node (B), and vice versa, via a high impedance path. In the illustrated example of FIG. 3, the state of the switch transistor 302 can be responsive to delayed control information (BBM_EN) received at an input 313. When the delayed control information (BBM_EN) includes a low logic level, the control node, or gate, of the switch transistor 302 can be pulled low and the well of the switch transistor 302 can be pulled to ground, thus, isolating the first switch node (A) from the second switch node (B) and vice versa. In certain examples, on a transition of the delayed control information (BBM_EN) from a low logic level to a high logic level, the logic level of the control node of the switch transistor 302 can be ramped from a low voltage level to a higher voltage level via a low pass filter, such as an resistor-capacitor (RC) network formed by the resistive element 312 of the control node electronics 311 and the structural capacitance of the switch transistor 302. In some examples, the control node electronics 311 can include a capacitive element that does not form a portion of the switch transistor 302 to form a portion of the GTO circuit low pass filter. In certain examples, the well biasing electronics 310 can bias the well of the switch transistor 302 in the on-state such that body diode effects of the switch transistor 302 do not substantially affect the fidelity of the signal passed between the first and second switch nodes (A, B).

In certain examples, on a transition of the delayed control information (BBM_EN) from a high logic level to a low logic level, the logic level of the control node of the switch transistor 302 can be switched from a high voltage level to a lower voltage level via the PMOS control switch 314 coupling the gate of the switch transistor 302 to ground. In certain examples, the transition of the gate of the switch transistor 302 can be ramped more gently from the high voltage level to the lower voltage level by adding a second resistive element between the gate of the switch transistor 302 and ground. It is understood that use of complementary components, such as a PMOS switch transistor, is possible without departing from the scope of the present subject matter.

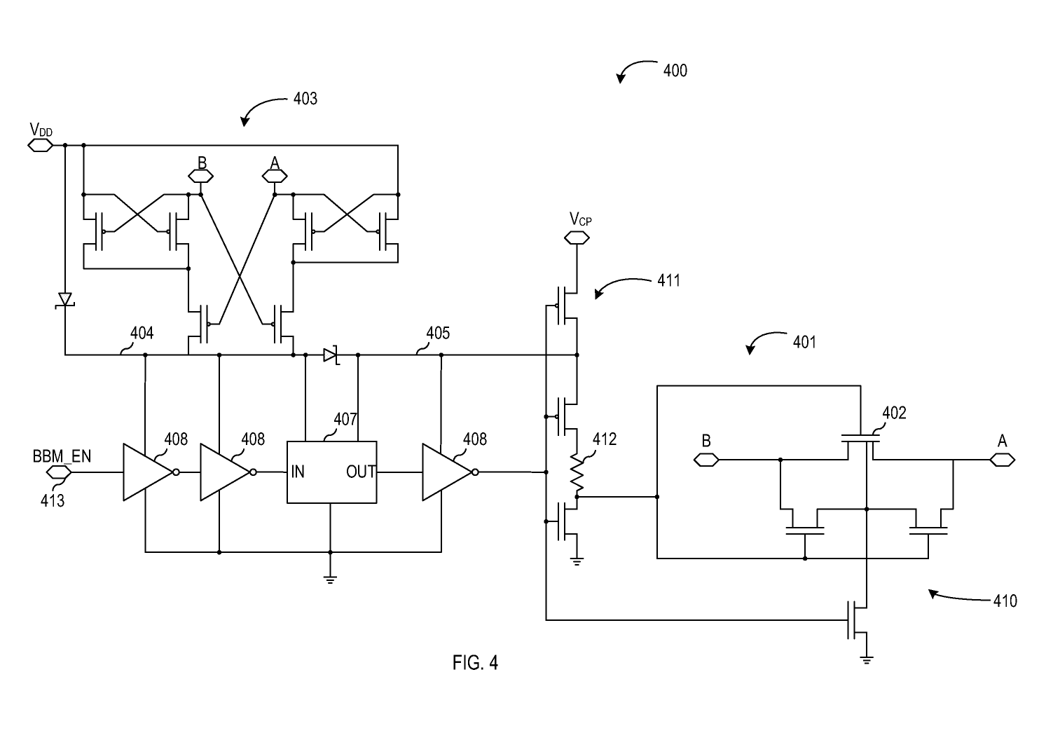

FIG. 4 illustrates generally an example of a high-speed (HS) Universal Serial Bus (USB) switch circuit 400 including a gradual turn-on (GTO) circuit 401 and configured to receive a delayed control information (BBM_EN) from a BBM delay circuit (not shown) such as the example of the BBM delay circuit 220 of FIG. 2. The HS USB switch circuit 400 can include a switch transistor 402 forming a portion of the GTO circuit 401. The switch transistor 402 can be coupled to a first switch node (A) and a second switch node (B).

The HS USB switch circuit 400 can also include an over-voltage circuit 403 configured to couple a first supply rail 404 to first supply voltage V_{DD} or a voltage present on switch node A or B. The first supply rail 404 can power at least a portion of the HS USB switch circuit 400 and can drive the switch transistor 402 in a particular mode of operation of the HS USB switch circuit 400. In certain examples, the HS USB switch circuit 400 can include a second supply rail 405 configured to couple to a second supply voltage, such as a charge pump voltage (V_{CP}) to drive the control node of the switch transistor 402. The HS USB switch circuit 400 can include a diode, such as a zener diode 406, to couple the first supply rail 404 to the second supply rail 405 when the second supply voltage (V_{CP}) is off, and can isolate the first supply rail 404 from the second supply rail 405 when the second supply voltage(V_{CP}) is on and the second supply rail 405 is at a voltage level higher than the first supply rail 404. In certain examples, the HS USB switch circuit 400 can also include a level shift circuit 407 to provide a proper logic level control signal to the switch transistor 402. In some examples, the HS USB switch circuit 400 can include additional logic devices 408 to provide the proper logic level signals to, or to buffer, the various components or signals of the HS USB switch circuit 400.

In certain examples, the switch transistor 402 can be configured to couple, via a low impedance path, a first switch node (A) and a second switch node (B) in an on-state, and to isolate the first switch node (A) from the second switch node (B), and vice versa, via a high impedance path. In the illustrated example of FIG. 4, the state of the switch transistor 402 can be responsive to delayed control information (BBM_EN) received at an input 413. When the delayed control information (BBM_EN) includes a low logic level, the control node, or gate, of the switch transistor 402 can be pulled low and the well of the switch transistor 402 can be pulled to ground via well biasing electronics 410, thus, isolating the first switch node (A) from the second switch node (B) and vice versa. In certain examples, on a transition of the delayed control information (BBM_EN) from a low logic level to a high logic level, the logic level of the control node of the switch transistor 402 can be ramped from a low voltage level to a higher voltage level via a low pass filter, such as an resistor-capacitor (RC) network formed by the resistive element 412 of the control node electronics 411 and the structural capacitance of the switch transistor 302. In some examples, the control node electronics 411 can include a capacitive element (not shown) that does not form a portion of the switch transistor 402 to form a portion of the GTO circuit low pass filter. In certain examples, the well biasing electronics 410 can bias the well of the switch transistor 402 in the on-state such that body diode effects of the switch transistor 402 do not substantially affect the fidelity of the signal passed between the first and second switch nodes (A, B).

In certain examples, one or more of the first and second switch terminals can be coupled to a terminal of a USB port, such as a USB port of a mobile electronic device.

### Additional Notes

In Example 1, a switch circuit can define an on-state and an off-state. When in the on-state, the switch circuit can couple a first node to a second node, and when in the off-state, the switch circuit can isolate the the first node from the second node. The switch circuit can include a switch transistor having a control node and coupled to the first node and the second node, a delay circuit configured to receive control information and to provide the control information after a delay interval, and a gradual turn-on circuit configured to receive the delayed control information from the delay circuit and to transition the transistor from the off-state to the on-state over a ramp interval in response to the delayed control information.

In Example 2, the delay circuit of Example 1 optionally includes a counter having a predetermined threshold count value, and an oscillator configured to provide clock information to the counter, the clock information configured to sequentially increment a count value of the counter.

In Example 3, the delay circuit of any one or more of Examples 1-2 optionally includes a plurality of cascaded delay elements.

In Example 4, one or more of the plurality of cascaded delay elements of any one or more of Examples 1-3 optionally includes a flip-flop.

In Example 5, the delay circuit of any one or more of Examples 1-4 optionally includes a clock to drive the plurality of cascaded delay elements during the delay interval.

In Example 6, the delay circuit of any one or more of Examples 1-5 optionally is configured to disable the clock after the delay interval.

In Example 7, the gradual turn-on circuit of any one or more of Examples 1-6 optionally includes a resistive element coupled to the control node of the switch transistor, and the resistive element and a capacitance of the switch transistor of any one or more of Examples 1-6 optionally are configured to reduce the impedance of the switch transistor between the first and second nodes over the ramp interval, and the ramp interval of any one or more of Examples 1-6 optionally is substantially determined using a value of the resistive element and a value of the switch capacitance.

In Example 8, an integrated circuit can include the switch transistor, the delay circuit, and the gradual turn-on circuit of any one or more of Examples 1-7.

In Example 9, the switch circuit of any one or more of Examples 1-8 optionally includes a universal serial bus (USB) terminal coupled to at least one of the first node or the second node.

In Example 10, the switch circuit of any one or more of Examples 1-9 optionally includes a charge pump configured to provide a control voltage to the control node of the switch transistor during at least one of the on-state or the off-state.

In Example 11, the switch circuit of any one or more of Example 1-10 optionally includes a high voltage translator configured to provide the control voltage if a voltage supply of the voltage translator is higher than a voltage of the charge pump.

In Example 12, the voltage supply of the voltage translator of any one or more of Examples 1-11 optionally includes at least one of a voltage at the first node, a voltage at the second node, or a voltage of a power supply.

In Example 13, a method can include receiving control information at a delay circuit, providing the control information at an output of the delay circuit after a delay interval, wherein the delay interval begins upon receiving the control information at the delay circuit, receiving the delayed control information at a gradual turn-on circuit of a switch circuit, and in response to the delayed control information, ramping a control voltage of a switch transistor over a ramp interval to gradually reduce an impedance of the switch transistor between a first node and a second node of the switch circuit.

In Example 14, the ramping a control voltage of any one or more of examples 1-13 optionally includes charging a capacitance of the switch transistor through a resistive element coupled to a control node of the switch transistor.

In Example 15, the providing the control information of any one or more of Examples 1-14 optionally includes delaying the control information using a plurality of cascaded delay elements.

In Example 16, the delaying the control information of any one or more of Examples 1-15 optionally includes passing the control information through the plurality of delay elements using an output of a clock.

In Example 17, the providing the control information of any one or more of Examples 1-16 optionally includes disabling the clock after the delay interval to save power.

Example 18 can include, or can optionally be combined with any portion or combination of any portions of any one or more of Examples 1-18 to include, subject matter that can include means for performing any one or more of the functions of

Examples 1-18, or a non transitory machine-readable medium including instructions that, when performed by a machine, cause the machine to perform any one or more of the functions of Examples 1-18.

The above detailed description includes references to the accompanying drawings, which form a part of the detailed description. The drawings show, by way of illustration, specific embodiments in which the invention can be practiced. These embodiments are also referred to herein as “examples.” All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. In some examples, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the invention should be determined with reference to the appended claims, along with the full scope of equivalents to which such claims are entitled.

What is claimed is:

1. A switch circuit defining an on-state and an off-state, the switch circuit, when in an on-state, couples a first node to a second node and, when in the off-state, isolates the the first node from the second node, the switch circuit comprising:
a switch transistor having a control node and coupled to the first node and the second node;
a delay circuit configured to receive control information and to provide the control information after a delay interval; and
a gradual turn-on circuit configured to receive the delayed control information from the delay circuit and to transition the transistor from the off-state to the on-state over a ramp interval in response to the delayed control information.

2. The switch circuit of claim 1, wherein the delay circuit includes:
a counter having a predetermined threshold count value; and
an oscillator configured to provide clock information to the counter, the clock information configured to sequentially increment a count value of the counter.

3. The switch circuit of claim 1, wherein the delay circuit includes a plurality of cascaded delay elements.

4. The switch circuit of claim 3, wherein one or more of the plurality of cascaded delay elements includes a flip-flop.

5. The switch circuit of claim 3, wherein the delay circuit includes a clock to drive the plurality of cascaded delay elements during the delay interval.

6. The switch circuit of claim 5, wherein the delay circuit is configured to disable the clock after the delay interval.

7. The switch circuit of claim 1, wherein the gradual turn-on circuit includes a resistive element coupled to the control node of the switch transistor;
wherein the resistive element and a capacitance of the switch transistor are configured to reduce the impedance of the switch transistor between the first and second nodes over the ramp interval; and
wherein the ramp interval is substantially determined using a value of the resistive element and a value of the switch capacitance.

8. The switch circuit of claim 1, wherein an integrated circuit can include the switch transistor, the delay circuit, and the gradual turn-on circuit.

9. The switch circuit of claim 1, including a universal serial bus (USB) terminal coupled to at least one of the first node or the second node.

10. The switch circuit of claim 1 including a charge pump configured to provide a control voltage to the control node of the switch transistor during at least one of the on-state or the off-state.

11. The switch circuit of claim 10, including a high voltage translator configured to provide the control voltage if a voltage supply of the voltage translator is higher than a voltage of the charge pump.

12. The switch circuit of claim 11, wherein the voltage supply of the voltage translator includes at least one of a voltage at the first node, a voltage at the second node, or a voltage of a power supply.

13. A method comprising:
receiving control information at a delay circuit;
providing the control information at an output of the delay circuit after a delay interval, wherein the delay interval begins upon receiving the control information at the delay circuit;
receiving the delayed control information at a gradual turn-on circuit of a switch circuit; and
in response to the delayed control information, ramping a control voltage of a switch transistor over a ramp interval to gradually reduce an impedance of the switch transistor between a first node and a second node of the switch circuit.

14. The method of claim 13, wherein ramping a control voltage includes charging a capacitance of the switch transistor through a resistive element coupled to a control node of the switch transistor.

15. The method of claim 13, wherein providing the control information includes delaying the control information using a plurality of cascaded delay elements.

16. The method of claim 15, wherein delaying the control information includes passing the control information through the plurality of delay elements using an output of a clock.

17. The method of claim 16, wherein providing the control information includes disabling the clock after the delay interval to save power.
